(19) United States
(12) Patent Application Publication
(10) Pub. No.: US 2023/0094213 A1
(43) Pub. Date: Mar. 30, 2023

(54) OPTICAL SCANNING DEVICE AND METHOD FOR MANUFACTURING THE SAME, AND DISTANCE MEASURING DEVICE

(71) Applicant: Mitsubishi Electric Corporation, Tokyo (JP)

(72) Inventors: Yusuke SHIRAYANAGI, Chiyoda ku, Tokyo (JP); Yoshitaka KAJIYAMA, Chiyoda ku, Tokyo (JP)

(73) Assignee: Mitsubishi Electric Corporation, Tokyo (JP)

(21) Appl. No.: 17/910,834

(22) PCT Filed: May 14, 2020
(86) PCT No.: PCT/JP2020/019295

§ 371 Date: Sep. 12, 2022

(51) Int. Cl. G02B 26/08; B81B 3/00; G01S 7/481; G01S 17/931; B81C 1/00

(52) U.S. Cl. CPC G02B 26/0833; B81B 3/0075; B81C 1/00293; G01S 7/4817; G01S 17/931; B81B 2201/042; B81B 2203/0154; C23C 16/45525

(57) ABSTRACT

An optical scanning device includes a reflector as a MEMS mirror having a reflection surface of a metal film, a support body, a drive beam, and a drive unit. The support body is disposed to be spaced from the reflector so as to surround the reflector. The drive beam connects the reflector and the support body. A first protection film is formed all over opposite side surfaces including side wall surfaces of a second semiconductor layer, as well as an upper surface and a lower surface, in the drive beam. As the first protection film, a silicon oxide film, a silicon nitride film, an alumina film, or a titania film is formed by an atomic layer deposition method.

### TECHNICAL FIELD

The present disclosure relates to an optical scanning device and a method for manufacturing the same, and a distance measuring device.

### BACKGROUND ART

Optical scanning devices are utilized for a laser distance sensor, a laser projector, a projection display, and the like. It has been known that MEMS (Micro Electro Mechanical System) technology is utilized for the optical scanning devices. By utilizing MEMS technology, cost reduction, downsizing, and higher accuracy are achieved. Generally, an optical scanning device includes a reflector which reflects a light beam, a support body which supports the reflector, and a drive unit which drives the reflector. The reflector is connected to the support body via a drive beam.

In an optical scanning device to which MEMS technology is applied, a reflector is driven by a drive unit which mainly utilizes an electrostatic force, a stress obtained by a piezoelectric film, or an electromagnetic force. By changing an angle of the reflector by an electrical signal, a laser beam or a light beam reflected by the reflector is emitted to an object while scanning the object. For a support body which supports the reflector, an SOI (Silicon On Insulator) substrate is mainly utilized. The SOI substrate is a substrate including a silicon layer formed on a silicon support substrate, with an oxide film being interposed therebetween.

An optical scanning device having a three-dimensional structure is manufactured by performing etching treatment on the SOI substrate (silicon). In particular, by utilizing a semiconductor process, a plurality of optical scanning devices can be manufactured as chips from an identical SOI substrate (wafer), which is effective to reduce manufacturing cost.

In an optical scanning device in which a reflector is connected to a support body via a drive beam, the drive beam is formed by deep processing performed on the SOI substrate utilizing a dry etching technique for silicon. Thus, side wall surfaces of the drive beam may be formed as scallop-shaped side wall surfaces. Further, the side wall surfaces of the drive beam may be damaged by plasma.

To address such a technical problem, for example, Patent Literature 1 proposes a technique of planarizing side wall surfaces of a drive beam and forming an oxide film. Further, Patent Literature 2 proposes a technique of forming a protection film in a movable unit of a dynamic sensor.

### Citation List

### Patent Literature

PTL 1: Japanese Patent Laying-Open No. 2013-35081
PTL 2: Japanese Patent Laying-Open No. H09-18019

### SUMMARY OF INVENTION

### Technical Problem

The optical scanning devices are required to have a longer life. To increase the life of the optical scanning devices, it is required to improve moisture resistance of a drive beam on which a load (stress) acts as a reflector is driven.

The present disclosure has been made under such development, and one object is to provide an optical scanning device having a longer life, and another object is to provide a method for manufacturing such an optical scanning device.

### Solution to Problem

An optical scanning device in accordance with the present disclosure includes a reflector, a support body, a drive beam, and a drive unit. The reflector has a reflection surface. The support body is disposed to be spaced from the reflector. The drive beam connects the reflector and the support body. The drive unit torsionally drives the reflector about the drive beam with respect to the support body. In the drive beam, all surfaces of the drive beam including side surfaces of the drive beam are covered with at least one layer of a protection film including a first protection film.

A method for manufacturing an optical scanning device in accordance with the present disclosure is a method for manufacturing an optical scanning device having a reflector, a support body, and a drive beam, the method including: preparing a substrate including a semiconductor layer formed on a support substrate with a first insulating film being interposed therebetween; forming a reflection film having a reflection surface to serve as the reflector, on the semiconductor layer, with a second insulating film being interposed therebetween; forming a drive unit to drive the reflector; and forming the reflector having the reflection film, the support body disposed to be spaced from the reflector, and the drive beam connecting the reflector and the support body, by performing processing on the second insulating film, the semiconductor layer, the first insulating film, and the support substrate. Forming the drive beam includes patterning the semiconductor layer to serve as the drive beam, by performing etching treatment, and forming at least one layer of a protection film including a first protection film, to cover all surfaces of the drive beam including side wall surfaces in a thickness direction of the patterned semiconductor layer.

### Advantageous Effects of Invention

According to the optical scanning device in accordance with the present disclosure, in the drive beam, all surfaces of the drive beam including side surfaces of the drive beam are covered with at least one layer of a protection film including a first protection film. Thereby, moisture resistance is improved, and the optical scanning device can have a longer life.

According to the method for manufacturing an optical scanning device in accordance with the present disclosure, forming the drive beam includes patterning the semiconductor layer to serve as the drive beam, by performing etching treatment, and forming at least one layer of a protection film including a first protection film, to cover all surfaces of the drive beam including side wall surfaces in a thickness direction of the patterned semiconductor layer. Thereby, it is possible to manufacture an optical scanning device which can achieve improved moisture resistance and can have a longer life.

### BRIEF DESCRIPTION OF DRAWINGS

FIG. 1 is a perspective view of an optical scanning device in accordance with a first embodiment.

FIG. 2 is a plan view of the optical scanning device in the embodiment.

FIG. 3 is a cross sectional view showing cross sectional views taken along a cross sectional line IIIa-IIIa, a cross sectional line IIIb-IIIb, and a cross sectional line IIIc-IIIc, respectively, shown in FIG. 2 in the embodiment.

FIG. 4 is a cross sectional view showing an example of a structure of a drive beam in the embodiment.

FIG. 5 is a cross sectional view showing one step of a method for manufacturing the optical scanning device in the embodiment.

FIG. 6 is a cross sectional view showing a step performed after the step shown in FIG. 5 in the embodiment.

FIG. 7 is a cross sectional view showing a step performed after the step shown in FIG. 6 in the embodiment.

FIG. 8 is a cross sectional view showing a step performed after the step shown in FIG. 7 in the embodiment.

FIG. 9 is a cross sectional view of an optical scanning device in accordance with a second embodiment.

FIG. 10 is a cross sectional view showing one step of a method for manufacturing the optical scanning device in the embodiment.

FIG. 11 is a cross sectional view showing a step performed after the step shown in FIG. 10 in the embodiment.

FIG. 12 is a cross sectional view showing a step performed after the step shown in FIG. 11 in the embodiment.

FIG. 13 is a cross sectional view showing a step performed after the step shown in FIG. 12 in the embodiment.

FIG. 14 is a cross sectional view showing a step performed after the step shown in FIG. 13 in the embodiment.

FIG. 15 is a cross sectional view of an optical scanning device in accordance with a third embodiment.

FIG. 16 is a cross sectional view showing an example of a structure of a drive beam in the embodiment.

FIG. 17 is a cross sectional view showing one step of a method for manufacturing the optical scanning device in the embodiment.

FIG. 18 is a cross sectional view showing a step performed after the step shown in FIG. 17 in the embodiment.

FIG. 19 is a cross sectional view showing a step performed after the step shown in FIG. 18 in the embodiment.

FIG. 20 is a cross sectional view showing a step performed after the step shown in FIG. 19 in the embodiment.

FIG. 21 is a cross sectional view showing a step performed after the step shown in FIG. 20 in the embodiment.

FIG. 22 is a plan view showing an optical scanning device that adopts an electrostatic drive-type drive unit as a drive unit in each embodiment.

FIG. 23 is a plan view showing an optical scanning device that adopts a piezoelectric drive-type drive unit as a drive unit in each embodiment.

FIG. 24 is a schematic view of a vehicle equipped with a distance measuring device to which an optical scanning device is applied, in accordance with a fourth embodiment.

FIG. 25 is a view schematically showing a structure of the distance measuring device in the embodiment.

### DESCRIPTION OF EMBODIMENTS

### First Embodiment

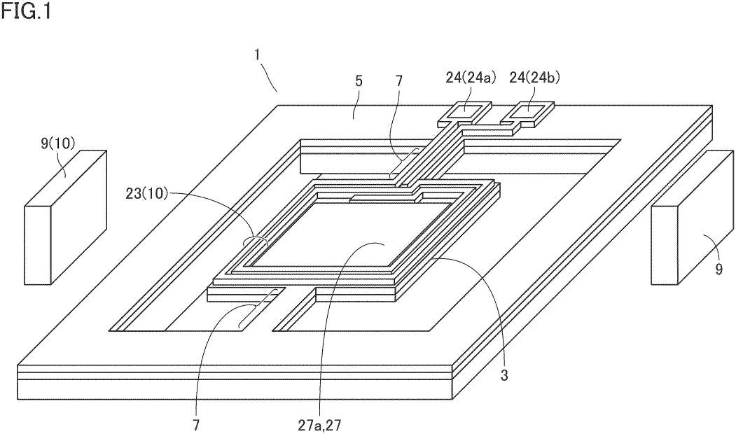

An example of an optical scanning device in accordance with a first embodiment will be described. As shown in FIG. 1, an optical scanning device 1 includes a reflector 3 as a MEMS mirror having a reflection surface 27a of a metal film 27, a support body 5, a drive beam 7, and a drive unit 10.

Support body 5 is disposed to be spaced from reflector 3 so as to surround reflector 3. Drive beam 7 connects reflector 3 and support body 5. Drive unit 10 is of an electromagnetic drive type, for example, and includes a first wire 23 disposed at reflector 3, and a pair of magnets 9. By drive unit 10, reflector 3 is torsionally driven about drive beam 7 with respect to support body 5.

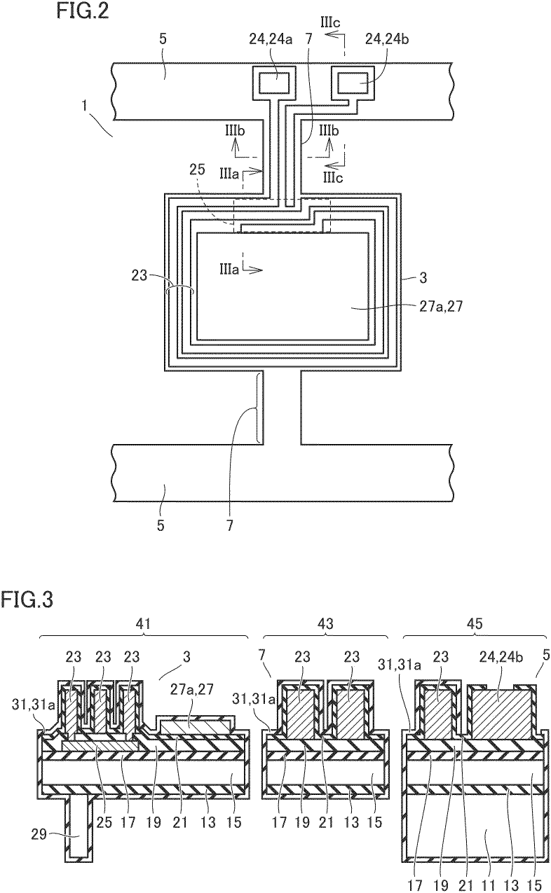

As shown in FIG. 2, first wire 23 is disposed in coil form along an outer peripheral edge of reflector 3. One end side of first wire 23 is electrically connected to an electrode pad 24a through a portion of first wire 23 disposed at drive beam 7. The other end side of first wire 23 is electrically connected to an electrode pad 24b through a portion of first wire 23 disposed at drive beam 7, via a second wire 25.

Electrode pads 24 (24a, 24b) are electrically connected with an external power source (not shown). The pair of magnets 9 are disposed to sandwich reflector 3 (support body 5) therebetween. By a Lorentz force based on an action between a current flowing through first wire 23 and magnetic field lines of magnets 9, reflector 3 is torsionally driven (rotated) about drive beam 7.

A structure of optical scanning device 1 will be described in detail. Optical scanning device 1 is formed from an SOI substrate 51, as described later (see FIG. 5). In SOI substrate 51, a second semiconductor layer 15 is formed on a first semiconductor layer 11 used as a support substrate, with a first insulating layer 13 being interposed therebetween.

As shown in FIG. 3, in a support body region 45, first semiconductor layer 11, first insulating layer 13, and second semiconductor layer 15 are stacked. A first insulating film 17 and a second insulating film 19 are stacked on one surface of second semiconductor layer 15. First wire 23 and electrode pad 24 are formed on second insulating film 19. A third insulating film 21 is formed to cover first wire 23 and a portion of electrode pad 24.

In a reflector region 41, first insulating film 17 is formed on one surface of second semiconductor layer 15. Second wire 25 is formed on first insulating film 17. Second insulating film 19 is formed to cover second wire 25. First wire 23 in coil form is formed on the second insulating film. The other end of first wire 23 is electrically connected to second wire 25. Third insulating film 21 is formed to cover first wire 23. Metal film 27 having reflection surface 27a of reflector 3 is formed on third insulating film 21. A rib 29 is formed on the other surface of second semiconductor layer 15, with first insulating layer 13 being interposed therebetween.

In a drive beam region 43, first insulating film 17 and second insulating film 19 are stacked on one surface of second semiconductor layer 15. The portions of first wire 23 electrically connected to first wire 23 in coil form are formed on second insulating film 19. Third insulating film 21 is formed to cover first wire 23. First insulating layer 13 is located on the other surface of second semiconductor layer 15.

In drive beam region 43, a first protection film 31a is formed as a protection film 31, all over opposite side surfaces including side wall surfaces of second semiconductor layer 15 exposed by patterning, as well as an upper surface and a lower surface, in drive beam 7. First protection film 31a is formed on the surfaces of drive beam 7 in a pinhole-free state without any gap, by an atomic layer deposition method (ALD method).

First protection film 31a is a passivation film, and may be a single layer film of a silicon oxide film, a silicon nitride film, an alumina film, or a titania film, for example. Alternatively, first protection film 31a may be a stacked layer film including at least two layers selected from a silicon oxide film, a silicon nitride film, an alumina film, and a titania film.

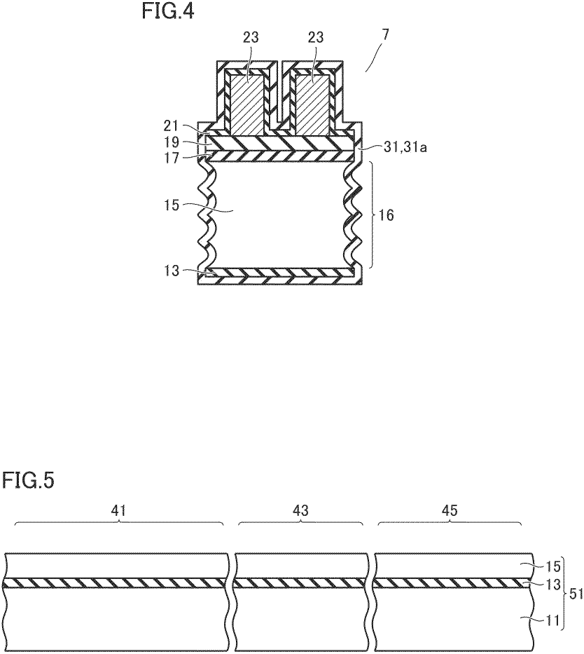

As described later, drive beam 7 and the like are formed by deep processing performed on the SOI substrate utilizing a dry etching technique. Thus, as shown in FIG. 4, the side surfaces of drive beam 7, specifically, side wall surfaces 16 of second semiconductor layer 15 as a beam body, may be formed as scallop-shaped side wall surfaces.

By forming pinhole-free first protection film 31a to cover all surfaces of drive beam 7 including the scallop-shaped side wall surfaces (side surfaces), moisture resistance can be improved. It should be noted that the scallop-shaped side wall surfaces of second semiconductor layer 14 may be planarized, and moisture resistance can be further improved by forming first protection film 31a on the planarized side wall surfaces of drive beam 7.

First protection film 31a is also formed in each of support body region 45 and reflector region 41, in addition to drive beam region 43. In support body region 45, first protection film 31a is formed to cover third insulating film 21, side wall surfaces of each of first semiconductor layer 11 and second semiconductor layer 15, and the like. In reflector region 41, first protection film 31a is formed to cover third insulating film 21, metal film 27, and the like. Optical scanning device 1 in accordance with the first embodiment is configured as described above.

Next, an example of a method for manufacturing optical scanning device 1 described above will be described. As shown in FIG. 5, first, SOI substrate 51 is prepared. In SOI substrate 51, second semiconductor layer 15 is formed on first semiconductor layer 11, with first insulating layer 13 being interposed therebetween. Silicon layers are applied as first semiconductor layer 11 and second semiconductor layer 15. Thermal oxidation treatment is performed on first semiconductor layer 11 to form first insulating layer 13. First insulating layer 13 is a buried oxide (BOX) film made of a silicon oxide film.

Second semiconductor layer 15 is formed on first insulating layer 13. First semiconductor layer 11 has a thickness of about 500 µm, for example. First insulating layer 13 has a thickness of about 1 µm, for example. Second semiconductor layer 15 has a thickness of about 50 µm, for example.

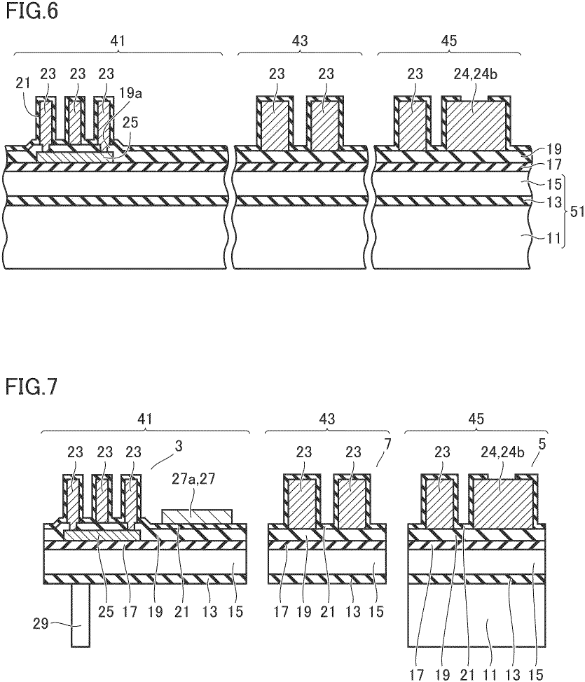

Subsequently, as shown in FIG. 6, first insulating film 17 is formed on the surface of second semiconductor layer 15. First insulating film 17 is formed by a thermal oxidation method. First insulating film 17 is a silicon oxide film (thermal oxide film), and has a film thickness of about 0.1 µm, for example. Then, second wire 25 is formed on first insulating film 17. Second wire 25 is formed by a chemical vapor deposition (CVD) method, for example.

First, a polysilicon thin film (not shown) doped with a high concentration of phosphorus or boron is formed. The polysilicon thin film has a film thickness of about 0.5 µm, for example. Then, photoengraving treatment is performed to form a resist mask (not shown). Then, using the resist mask as an etching mask, dry etching treatment such as reactive ion etching is performed, and thereby second wire 25 is patterned.

Subsequently, second insulating film 19 is formed on first insulating film 17 to cover second wire 25. Second insulating film 19 is formed by a low-pressure CVD method, an atmospheric-pressure CVD method, a plasma-excited CVD method, a sputtering method, or a coating method, for example. Second insulating film 19 is a silicon oxide film (SiO₂), a silicon oxide film doped with phosphorus (PSG: Phospho Silicate Glass), a silicon oxide film doped with boron (BSG: Boro Silicate Glass), a silicon oxide film doped with boron and phosphorus (BPSG: Boro Phospho Silicate Glass), a TEOS (Tetra EthOxy Silane) film, an SOG (Spin On Glass) film, or the like, for example. Second insulating film 19 has a film thickness of about 1.0 µm, for example.

Subsequently, photoengraving treatment and dry etching treatment are performed on second insulating film 19 to form 19a which exposes second wire 25. Then, first wire 23 is formed on second insulating film 19. First wire 23 is formed by the sputtering method, a plating method, or the like, for example.

First, a titanium (Ti) film or a titanium nitride (TiN) film is formed to improve adhesiveness between first wire 23 and a base. Then, a metal film having good conductivity, such as an aluminum (Al) film, an aluminum silicide (AlSi) film, an aluminum-copper (AlCu) alloy film, an aluminum nitride (AIN) film, or a copper (Cu) film, for example, is formed.

Further, a titanium (Ti) film or a titanium nitride (TiN) film is formed to improve corrosion resistance of the aluminum film or the like. Then, photoengraving treatment and dry etching treatment such as RIE or wet etching treatment using an etchant solution are performed, and thereby first wire 23 is patterned.

Subsequently, third insulating film 21 is formed. Third insulating film 21 is formed by the plasma-excited CVD method, the coating method, the sputtering method, or the like, for example. Third insulating film 21 is a silicon oxide (SiO₂) film, a TEOS film, a PSG film, a BSG film, an SOG film, a silicon nitride film, or the like, for example. Third insulating film 21 has a film thickness of about 0.1 µm. Thereby, a first structural body including first wire 23 and the like for driving the reflector is formed on SOI substrate 51.

Subsequently, etching treatment is performed on the SOI substrate, and thereby the reflector, the support body, and the drive beam are patterned.

First, metal film 27 (see FIG. 7) to serve as the reflector is formed to cover the third insulating film. Metal film 27 is formed by the sputtering method, a vacuum deposition method, or the like, for example. After metal film 27 is formed, photoengraving treatment and etching treatment are performed, and thereby metal film 27 is patterned in reflector region 41. As metal film 27 having reflection surface 27a, a metal film having a high reflectivity with respect to the wavelength of scanned light is desirable.

When the scanned light is infrared light, for example, a gold (Au) film is suitable. When a gold film is formed, a film for improving adhesiveness with a base is desirably interposed between the gold film and the base. For example, chromium (Cr) film/nickel (Ni) film/gold film, or titanium (Ti) film/platinum (Pt) film/gold film is preferable.

Subsequently, photoengraving treatment is performed, and dry etching treatment is sequentially performed on third insulating film 21, second insulating film 19, first insulating film 17, second semiconductor layer 15, and first insulating layer 13, to perform patterning. Second semiconductor layer 15 is etched by deep processing such as a BOSCH method developed by BOSCH. In this deep processing (etching), first insulating layer 13 acts as an etching stopper layer.

In this deep processing, the side wall surfaces of second semiconductor layer 15 are formed in a scallop shape (see FIG. 4). By performing chemical dry etching (CDE) treatment, for example, on the scallop-shaped side wall surfaces of second semiconductor layer 15, the side wall surfaces of second semiconductor layer 15 are isotropically etched, and the side wall surfaces are planarized. Thereafter, dry etching treatment is performed on first insulating layer 13 to expose first semiconductor layer 11.

Subsequently, photoengraving treatment is performed, and dry etching treatment is performed on first semiconductor layer 11, to form the reflector, the support body, and the drive beam as shown in FIG. 7. First semiconductor layer 11 is etched by deep processing such as the BOSCH method. Rib 29 is formed in reflector 3 to improve rigidity of reflector 3. Thereby, a second structural body in which reflector 3, support body 5, and drive beam 7 are patterned is formed.

Subsequently, first protection film 31a is formed as protection film 31 on patterned drive beam 7 and the like (see FIG. 3). First protection film 31a is formed by the ALD method, for example, and pinhole-free first protection film 31a is continuously formed on all surfaces of drive beam 7 including the side wall surfaces of drive beam 7, without any gap. As the ALD method, a thermal ALD method or a plasma ALD method is used, for example.

First protection film 31a is a passivation film, and is formed from a silicon oxide film, a silicon nitride film, an alumina film, or a titania film, for example. The passivation film has an insulating property and moisture resistance. The film forming temperature is preferably a temperature at which first wire 23 is less affected, and is preferably less than or equal to 300° C., for example, and is more preferably about 150° C. to 250° C.

When first protection film 31a is formed by the ALD method, first protection film 31a is formed on all surfaces of the second structural body including reflector 3, support body 5, and drive beam 7. Accordingly, first protection film 31a is also formed on a surface of electrode pad 24. In electrode pad 24, it is necessary to expose the surface of electrode pad 24 to allow a current to flow from the external power source.

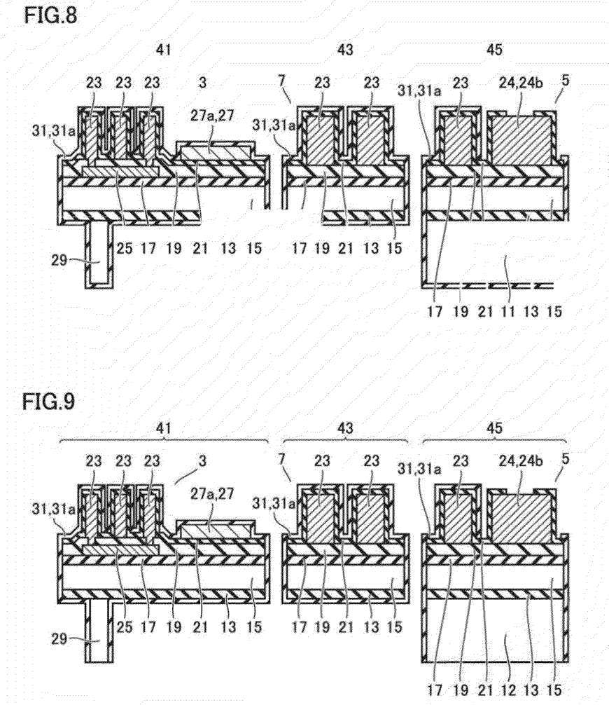

Thus, when first protection film 31a is formed, a heat-resistant coating is formed beforehand on the surface of electrode pad 24. By forming first protection film 31a in that state and thereafter removing the coating, the surface of electrode pad 24 is exposed. Thereby, as shown in FIG. 8, first protection film 31a is formed on all surfaces of the second structural body including reflector 3, support body 5, and drive beam 7, except for the surface of electrode pad 24.

Subsequently, an act of taking out the second structural body, in which first protection film 31a is formed to cover reflector 3, support body 5, and drive beam 7, as a chip, from the SOI substrate is performed. For example, by performing dicing along dicing lines by stealth laser dicing or blade dicing, optical scanning device 1 including reflector 3, support body 5, and drive beam 7 is taken out as a chip. Thus, optical scanning device 1 shown in FIG. 1 and the like is completed.

Generally, in an optical scanning device which utilizes the Lorentz force, a reflector is torsionally driven (rotated) about a drive beam. Accordingly, a stress is likely to concentrate on the drive beam, and it is conceivable that the drive beam may be broken. In particular, it is conceivable that silicon constituting the drive beam may be degraded under the influence of an external environment such as humidity, and durability of the drive beam may be deteriorated. As a result, it is conceivable that the time taken until the drive beam is broken is reduced, when compared with a case where the external environment has no influence.

In contrast, in optical scanning device 1 described above, first protection film 31a is continuously formed as protection film 31, over all surfaces of drive beam 7 including the side wall surfaces of drive beam 7. First protection film 31a is a pinhole-free passivation film formed by the ALD method. The passivation film is, for example, a single layer film of a silicon oxide film, a silicon nitride film, an alumina film, or a titania film, or a stacked layer film including at least two layers selected from a silicon oxide film, a silicon nitride film, an alumina film, and a titania film.

Thereby, it is possible to more effectively prevent penetration of moisture into drive beam 7 on which a stress acts as reflector 3 is driven. As a result, durability of drive beam 7 is significantly improved, and optical scanning device 1 can have a longer life.

### Second Embodiment

In the optical scanning device described above, an example of the optical scanning device formed from the SOI substrate has been described. Here, an example of an optical scanning device formed from a C-SOI (Cavity Silicon On Insulator) substrate will be described.

Optical scanning device 1 is formed from a C-SOI substrate having a cavity formed therein. In this case, the first protection film is also formed on surfaces of a third semiconductor layer having a cavity formed therein, and the optical scanning device is formed by performing processing on the third semiconductor layer having the first protection film formed thereon.

Accordingly, as shown in FIG. 9, in reflector region 41 in optical scanning device 1, first protection film 31a is formed to cover reflector 3, except for a portion of a surface of rib 29 formed from a portion of the third semiconductor layer. In support body region 45, first protection film 31a is formed to cover support body 5, except for a portion of a surface of a third semiconductor layer 12.

On the other hand, in drive beam region 43, first protection film 31a is formed to continuously cover all surfaces of drive beam 7. It should be noted that, since optical scanning device 1 has a configuration similar to the configuration of optical scanning device 1 shown in FIG. 3 except for the matters described above, identical members will be designated by the same reference numerals, and the description thereof will not be repeated except when necessary.

Next, an example of a method for manufacturing optical scanning device 1 described above will be described. Optical scanning device 1 is formed from a C-SOI substrate. First, a method for manufacturing the C-SOI substrate will be described. Thermal oxidation treatment is performed on a surface of third semiconductor layer 12 (see FIG. 10) used as a support substrate, to form a thermal oxide film (not shown). Photoengraving treatment and etching treatment are performed on the thermal oxide film to form a pattern (not shown) of the thermal oxide film for forming a cavity.

Using the pattern of the thermal oxide film as an etching mask, etching treatment is performed on third semiconductor layer 12 to form a cavity 12a (see FIG. 10). Subsequently, thermal oxidation treatment is performed on second semiconductor layer 15 to form first insulating layer 13 (see FIG. 10). Then, third semiconductor layer 12 having cavity 12a formed therein is joined to first insulating layer 13 formed on second semiconductor layer 15, to form a C-SOI substrate 53 having cavity 12a as shown in FIG. 10.

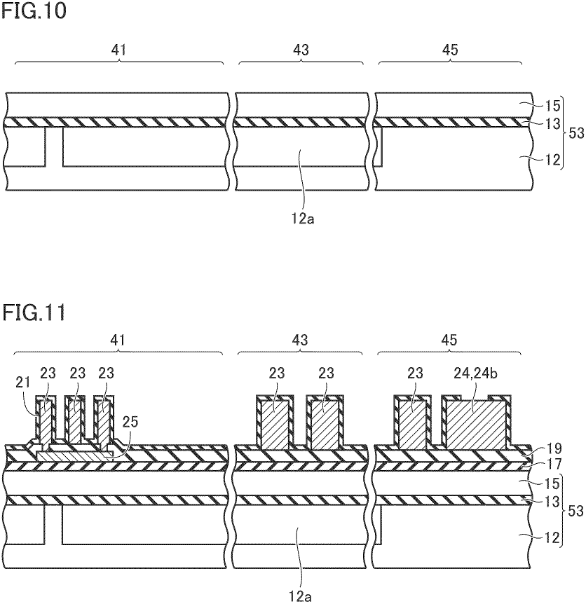

Subsequently, through the same step as the step shown in FIG. 6, as shown in FIG. 11, in reflector region 41, first wire 23 and third insulating film 21 covering first wire 23 are formed. In drive beam region 43, first wire 23 and third insulating film 21 covering the first wire are formed. In support body region 45, first wire 23 and third insulating film 21 covering first wire 23 are formed, and electrode pad 24b and third insulating film 21 covering a portion of electrode pad 24b are formed. Thus, a third structural body including first wire 23 for driving the reflector is formed on C-SOI substrate 53.

Subsequently, as in the step shown in FIG. 7, metal film 27 having reflection surface 27a is formed in reflector region 41 (see FIG. 12). Then, photoengraving treatment is performed, and dry etching treatment is sequentially performed on third insulating film 21, second insulating film 19, first insulating film 17, second semiconductor layer 15, and first insulating layer 13 by the same etching technique as that in the step shown in FIG. 7, to perform patterning including openings 53a which are in communication with cavity 12a. Thereby, as shown in FIG. 12, a fourth structural body including drive beam 7 is formed.

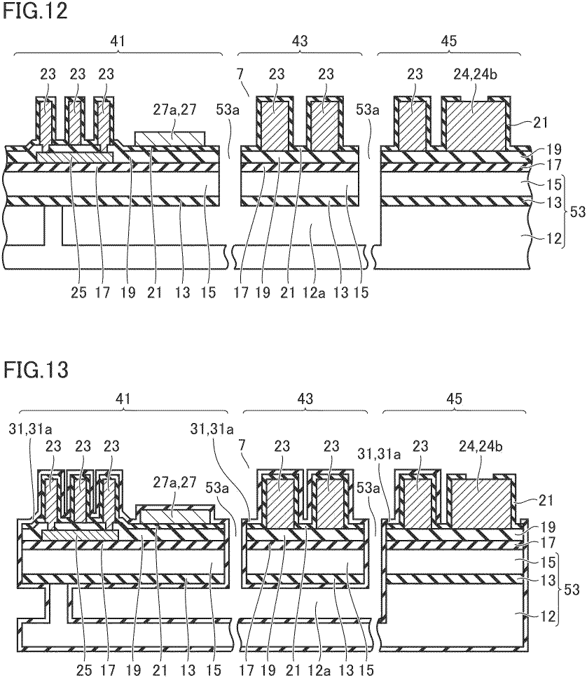

Subsequently, as shown in FIG. 13, first protection film 31a is formed as protection film 31 on patterned drive beam 7 and the like. By the same technique as that in the step shown in FIG. 8, that is, by the ALD method, pinhole-free first protection film 31a is continuously formed on all surfaces of drive beam 7 including the side wall surfaces of drive beam 7, without any gap. Thus, a fifth structural body including drive beam 7 whose surfaces are all covered with first protection film 31a is formed.

When first protection film 31a is formed by the ALD method, first protection film 31a is formed on all surfaces of the fourth structural body including the drive beam. Accordingly, as in the technique shown in FIG. 8, in electrode pad 24, the surface of electrode pad 24 is exposed to allow a current to flow from the external power source.

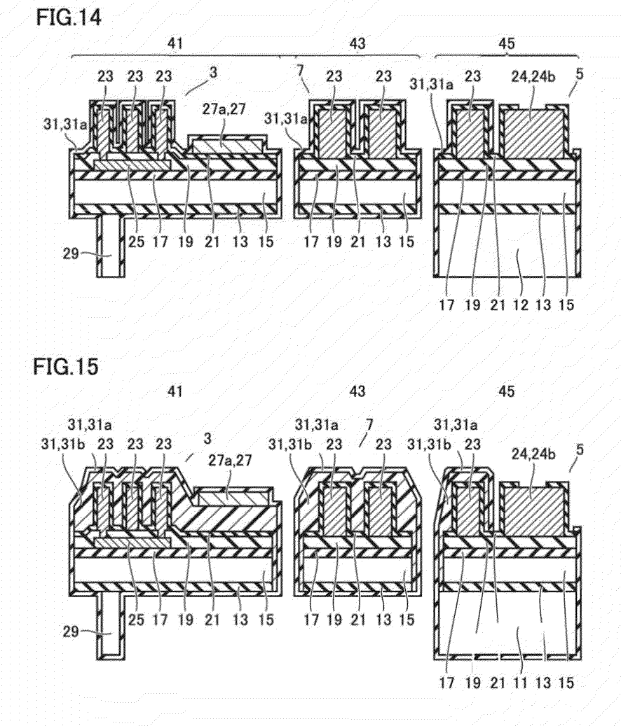

Subsequently, as shown in FIG. 14, etching treatment is performed on third semiconductor layer 12 (a back surface side of C-SOI substrate 53) located in reflector region 41 and drive beam region 43 until cavity 12a is reached, to form a main portion of the optical scanning device including reflector 3, drive beam 7, and support body 5. Thereafter, an act of taking out optical scanning device 1 as a chip from the C-SOI substrate is performed, and thereby optical scanning device 1 shown in FIG. 9 is completed.

In optical scanning device 1 described above, pinhole-free first protection film 31a (passivation film) is continuously formed as protection film 31 by the ALD method, over all surfaces of drive beam 7 including the side wall surfaces of drive beam 7. Thereby, as has been already described, it is possible to more effectively prevent penetration of moisture into drive beam 7 on which a stress acts as reflector 3 is driven. As a result, moisture resistance of drive beam 7 is significantly improved, and optical scanning device 1 can surely have a longer life.

Further, in optical scanning device 1 described above, optical scanning device 1 is formed by processing the C-SOI substrate. In this case, first protection film 31a is formed before performing etching treatment on third semiconductor layer 12 (see FIG. 13). Accordingly, first protection film 31a can be formed before reducing thicknesses of reflector region 41 and drive beam region 43, and it is possible to prevent a damage to C-SOI substrate 53, such as a crack in C-SOI substrate 53, when C-SOI substrate 53 is handled.

It should be noted that, it is also possible to apply a structure in a state before etching treatment is performed on third semiconductor layer 12, that is, the fifth structural body shown in FIG. 13, as optical scanning device 1.

### Third Embodiment

Here, an example of an optical scanning device including a drive beam covered with a protection film having a plurality of layers will be described.

As shown in FIG. 15, optical scanning device 1 includes reflector 3 as a MEMS mirror, support body 5, drive beam 7, and drive unit 10 (see FIG. 1). As shown in FIGS. 15 and 16, in drive beam region 43, protection film 31 is formed over all surfaces of drive beam 7 including the side wall surfaces of second semiconductor layer 15 as the beam body exposed by patterning. Protection film 31 includes first protection film 31a and a second protection film 31b.

Second protection film 31b is formed to cover third insulating film 21, and cover end surfaces of each of the third insulating film, second insulating film 19, and first insulating film 17, as well as the side wall surfaces of second semiconductor layer 15. Second protection film 31b is a resin film, and an acrylic resin film, a polyimide-based resin film, or an epoxy-based resin film is applied.

First protection film 31a is continuously formed on the surfaces of drive beam 7 without any gap, to cover second protection film 31b and the like. First protection film 31a is a pinhole-free passivation film formed by the ALD method, and is, for example, a silicon oxide film, a silicon nitride film, an alumina film, or a titania film, for example.

As shown in FIG. 15, first protection film 31a and second protection film 31b are also formed in each of support body region 45 and reflector region 41, in addition to drive beam region 43. In support body region 45, second protection film 31b is formed to cover third insulating film 21. First protection film 31a is formed to cover third insulating film 21, the side wall surfaces of each of first semiconductor layer 11 and second semiconductor layer 15, second protection film 31b, and the like.

In reflector region 41, second protection film 31b is formed to cover third insulating film 21. First protection film 31a is formed to cover third insulating film 21, second protection film 31b, metal film 27, and the like. It should be noted that, since optical scanning device 1 has a configuration similar to the configuration of optical scanning device 1 shown in FIGS. 3 and 4 except for the matters described above, identical members will be designated by the same reference numerals, and the description thereof will not be repeated except when necessary. Optical scanning device 1 in accordance with a third embodiment is configured as described above.

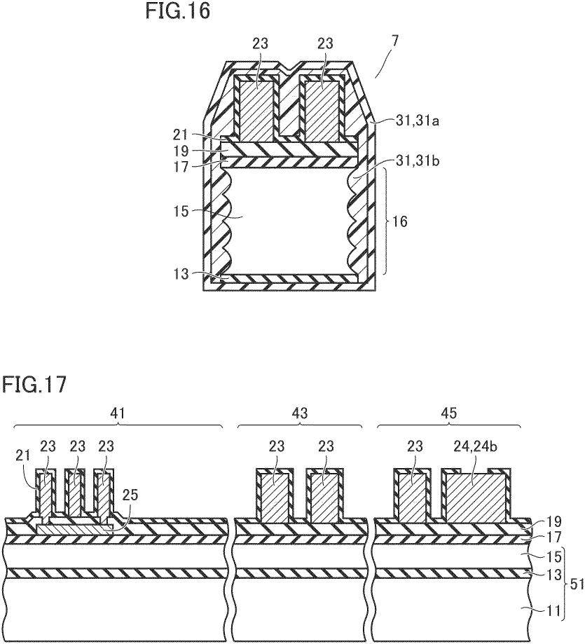

Next, an example of a method for manufacturing optical scanning device 1 described above will be described. Through the same steps as the steps shown in FIGS. 5 and 6, as shown in FIG. 17, in reflector region 41, first wire 23 and third insulating film 21 covering first wire 23 are formed. In drive beam region 43, first wire 23 and third insulating film 21 covering the first wire are formed. In support body region 45, first wire 23 and third insulating film 21 covering first wire 23 are formed, and electrode pad 24b and third insulating film 21 covering a portion of electrode pad 24b are formed. Thus, the first structural body including first wire 23 for driving the reflector is formed on SOI substrate 51.

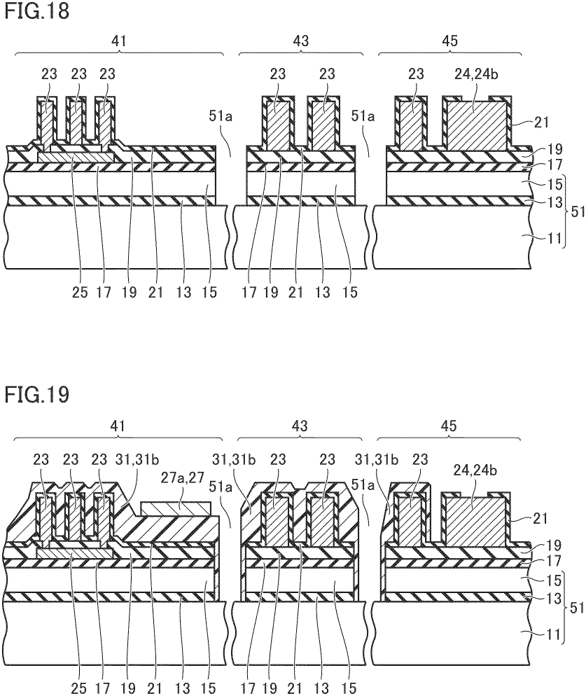

Subsequently, as shown in FIG. 18, photoengraving treatment and etching treatment are performed to form openings 51a which expose first semiconductor layer 11. Openings 51a are formed in a pattern corresponding to reflector 3, drive beam 7, and support body 5 (see FIG. 15). Openings 51a are formed by performing photoengraving treatment and sequentially performing dry etching treatment on third insulating film 21, second insulating film 19, first insulating film 17, second semiconductor layer 15, and first insulating layer 13.

Second semiconductor layer 15 is etched by deep processing such as the BOSCH method. In this deep processing (etching), first insulating layer 13 acts as an etching stopper layer. The scallop-shaped side wall surfaces of second semiconductor layer 15 formed in this deep processing can be planarized by performing chemical dry etching treatment, for example. Thus, a sixth structural body having a pattern of openings 51a corresponding to reflector 3, drive beam 7, and support body 5 is formed.

Subsequently, as shown in FIG. 19, second protection film 31b is formed to cover third insulating film 21. Second protection film 31b is formed to cover all surfaces of third insulating film 21, by spray coating which can uniformly coat a stepped portion. As second protection film 31b, for example, an acrylic resin film, a polyimide-based resin film, or an epoxy-based resin film is preferable. Further, as second protection film 31b, a light-sensitive material may be applied.

Second protection film 31b has a film thickness of preferably more than or equal to 1 µm, and more preferably 1 to 4 µm. Subsequently, photoengraving treatment and etching treatment are performed to remove portions of second protection film 31b located in openings 51a and a portion of second protection film 31b covering electrode pad 24. Then, heat treatment is performed under a temperature condition of about 200° C., to cure second protection film 31b and bring it into close contact with a base. Thus, a seventh structural body having second protection film 31b formed thereon is formed.

Subsequently, as in the step shown in FIG. 12, metal film 27 to serve as the reflector is formed to cover second protection film 31b. Then, photoengraving treatment and etching treatment are performed, and thereby metal film 27 having reflection surface 27a is patterned in reflector region 41.

Subsequently, as shown in FIG. 20, etching treatment is performed on first semiconductor layer 11 (a back surface side of SOI substrate 51) until openings 51a are reached, and thereby reflector 3, drive beam 7, and support body 5 are patterned. Rib 29 for improving rigidity is formed in reflector 3. Thus, an eighth structural body including reflector 3, drive beam 7, and support body 5 is formed.

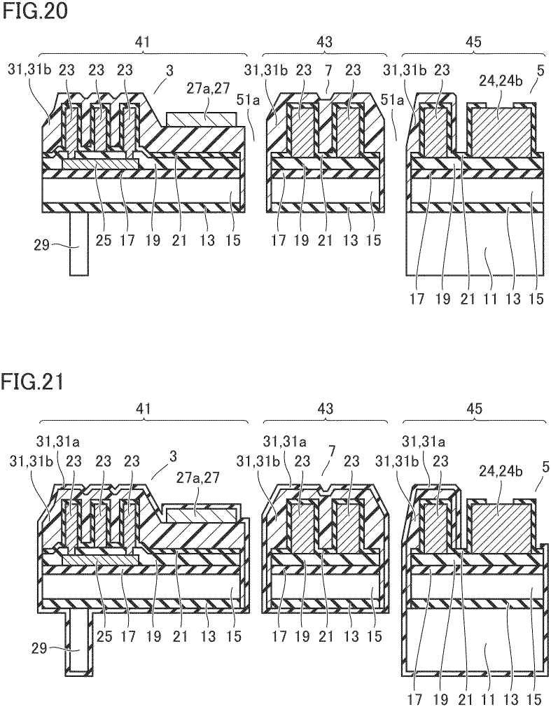

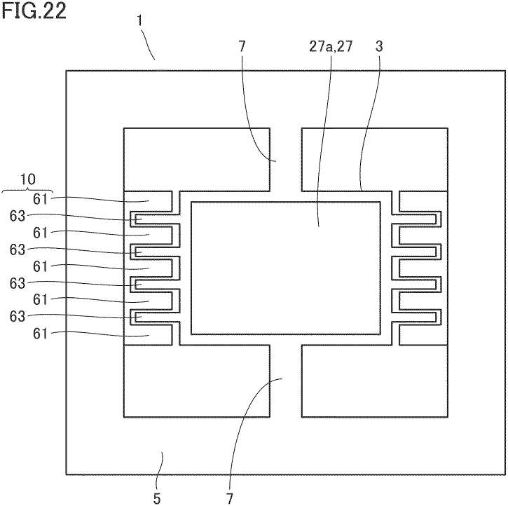

Subsequently, as shown in FIG. 21, first protection film 31a is formed on patterned drive beam 7 and the like. By the same technique as that in the step shown in FIG. 8, that is, by the ALD method, pinhole-free first protection film 31a is continuously formed on all surfaces of drive beam 7 including the side wall surfaces of drive beam 7, without any gap. It should be noted that, in electrode pad 24, the surface of electrode pad 24 is exposed to allow a current to flow from the external power source. Thereafter, an act of taking out optical scanning device 1 as a chip from the SOI substrate is performed, and thereby optical scanning device 1 shown in FIG. 15 is completed.

In optical scanning device 1 described above, pinhole-free first protection film 31a (passivation film) is continuously formed as protection film 31 by the ALD method, over all surfaces of drive beam 7 including the side wall surfaces of drive beam 7. Thereby, as has been already described, it is possible to more effectively prevent penetration of moisture into drive beam 7 on which a stress acts as reflector 3 is driven, and moisture resistance of drive beam 7 can be significantly improved.

Further, in optical scanning device 1 described above, in addition to first protection film 31a, second protection film 31b is formed as protection film 31. Thereby, moisture resistance can be further improved. As a result, optical scanning device 1 can have a longer life.

It should be noted that, in each optical scanning device 1 described above, the description has been given of a case where drive unit 10 is electromagnetic drive-type drive unit 10 that utilizes the Lorentz force caused by an action between a current flowing through first wire 23 and magnetic field lines of magnets 9. Drive unit 10 is not limited to an electromagnetic drive-type drive unit, and may be an electrostatic drive-type drive unit or a piezoelectric drive-type drive unit.

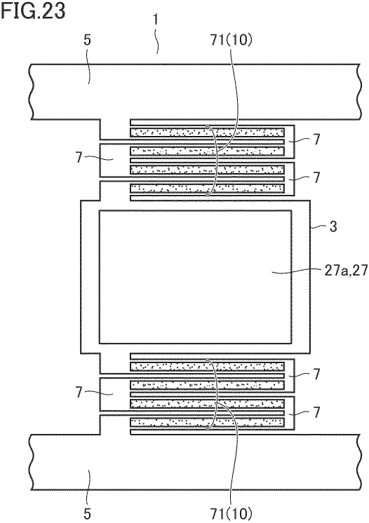

As shown in FIG. 22, electrostatic drive-type drive unit 10 includes a fixed comb-like electrode 61 and a movable comb-like electrode 63. Fixed comb-like electrode 61 is formed at support body 5. Movable comb-like electrode 63 is formed at reflector 3. In this optical scanning device 1, reflector 3 is torsionally driven about drive beam 7, by an electrostatic force of a charge generated by a voltage applied to fixed comb-like electrode 61 and a voltage applied to movable comb-like electrode 63.

As shown in FIG. 23, piezoelectric drive-type drive unit 10 includes a piezoelectric film 71. Piezoelectric film 71 has a function of converting an electrical signal into a stress, and is formed on a surface of drive beam 7. As piezoelectric film 71, for example, lead zirconate titanate (PZT: Pb(Zr, Ti)O₃), aluminum nitride (AlN), or the like is applied. A film stress is generated by applying a voltage to piezoelectric film 71, and drive beam 7 deforms due to an inverse piezoelectric effect. Reflector 3 is driven by the deformation of drive beam 7.

### Fourth Embodiment

Here, a distance measuring device to which optical scanning device 1 described in each embodiment is applied will be described.

A distance measuring device is a device for measuring a distance from a light source to a target, by emitting a light beam from the light source toward the target and receiving a light beam reflected by the target. The light beam reflected by the target is called a returned light beam.

In recent years, a distance measuring device using a laser beam, for example, is applied in automated driving of a car. In the distance measuring device, presence or absence of an obstacle is detected by whether or not a reflected light beam is received when a laser beam is emitted. Further, in the distance measuring device, a distance to the obstacle is calculated based on a time difference between timing at which the laser beam is emitted and timing at which the reflected light beam is received.

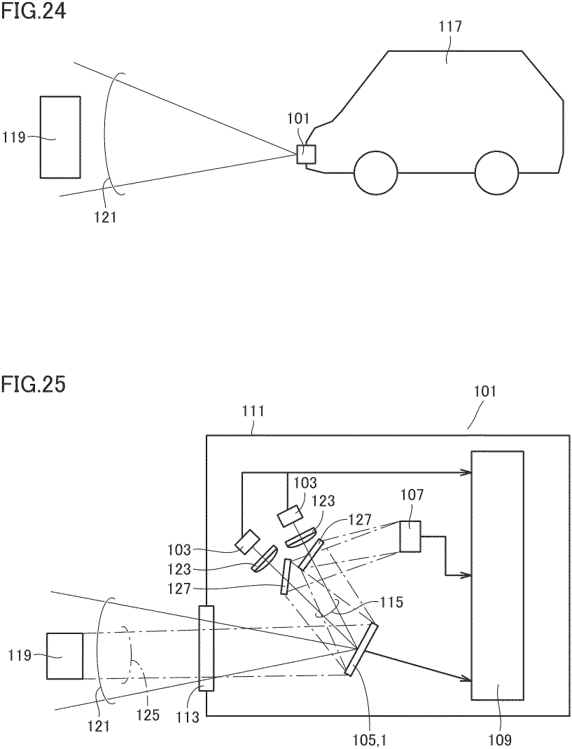

In the following, a distance measuring device in accordance with a fourth embodiment will be described. FIG. 24 schematically shows a vehicle 117 equipped with a distance measuring device 101. As shown in FIG. 24, distance measuring device 101 is installed at the front of vehicle 117, for example. Distance measuring device 101 detects a target 119 ahead. Distance measuring device 101 calculates a distance from vehicle 117 to target 119. Target 119 is another vehicle, a bicycle, a pedestrian, or the like, for example. In distance measuring device 101, an emitted light beam 121 is emitted, and a reflected light beam 125 (see FIG. 25) from target 119 is detected. In distance measuring device 101, a distance image is generated based on detected reflected light beam 125.

### Overall Configuration of Distance Measuring Device

FIG. 25 schematically shows a configuration of distance measuring device 101. Distance measuring device 101 includes a plurality of light sources 103, lenses 123, a mirror 105 (on a light emitting side), mirrors 127 (on a light receiving side), a light receiving unit 107, and a control unit 109. As mirror 105, for example, optical scanning device 1 described in the first embodiment or the like is applied. This optical system is housed inside a case 111. Case 111 is provided with a window 113. In the following, each unit will be specifically described.

### Light Source

Light source 103 emits a light beam 115. Light source 103 is a laser light source or the like, for example. Distance measuring device 101 can include a plurality of light sources 103. Although FIG. 25 shows two light sources 103, distance measuring device 101 may include only one light source.

### Light Beam

Light beam 115 is a laser beam emitted from light source 103. The laser beam has a wavelength of about 870 nm to 1500 nm, for example.

### Lens

Lens 123 changes light distribution of light beam 115 emitted from light source 103. Light distribution means spatial distribution of a light beam emitted from a light source in all directions. Lens 123 changes light distribution such that emitted light beam 121 emitted from distance measuring device 101 may become a parallel light beam. Lens 123 is a convex lens, a cylindrical lens, a toroidal lens, or the like, for example. A plurality of, that is, two or more lenses may be used as lenses 123. It should be noted that lenses 123 may be omitted as long as emitted light beam 121 is emitted from distance measuring device 101 as a parallel light beam.

### Mirror

Mirror 105 is reflection surface 27a (see FIG. 1) of reflector 3 of optical scanning device 1 of any one of the first to third embodiments. Mirror 105 reflects light beams 115 emitted from light sources 103 and penetrating lenses 123. Light beams 115 reflected by mirror 105 are emitted from distance measuring device 101 as emitted light beam 121.

Reflector 3 having reflection surface 27a to serve as mirror 105 is torsionally driven (rotated) about drive beam 7 (see FIG. 1). Torsional driving is a reciprocating motion. As mirror 105 is torsionally driven, emitted light beam 121 is scanned in two dimensions. Light beams 115 emitted from the plurality of light sources 103 are reflected by mirror 105 in respective different directions.

### Emitted Light Beam

Emitted light beam 121 is a laser beam emitted from distance measuring device 101. Emitted light beam 121 includes light beams 115 emitted from the plurality of light sources 103 and reflected by mirror 105. Emitted light beam 121 is a parallel light beam. A beam waist at which emitted light beam 121 has its minimum diameter is set to 60 meters ahead, for example. Emitted light beam 121 is a pulsed light beam. The pulse width is 1 ns to 10 ns, for example. Emitted light beam 121 is emitted to target 119.

### Reflected Light Beam

Reflected light beam 125 is a light beam (component) traveling from target 119 toward distance measuring device 101, of emitted light beam 121 emitted to target 119 and reflected at target 119.

### Light Receiving Unit

Light receiving unit 107 detects a light beam. Light receiving unit 107 includes a light receiving element that detects a light beam, for example. The light receiving element is a photodiode, an avalanche photodiode, or the like, for example. Light receiving unit 107 senses reflected light beam 125 traveling from target 119 toward distance measuring device 101 and reflected at mirror 105 and mirrors 127.

It should be noted that, since reflected light beam 125 reflected at mirror 105 travels toward light sources 103, light receiving unit 107 may be disposed near light sources 103. By disposing mirrors 127, light receiving unit 107 can be disposed at a position away from light sources 103. In light receiving unit 107, a lens that concentrates reflected light beam 125 (not shown) may be disposed.

### Mirror

Mirrors 127 reflect reflected light beam 125 reflected at mirror 105 toward light receiving unit 107. Desirable mirror 127 is, for example, a mirror having a through hole formed at the center, such that light beam 115 emitted from light source 103 passes therethrough. Further, as mirror(s) 127, one or a plurality of mirrors disposed at a position(s) deviated from light paths of light beams 115 emitted from light sources 103 may be used. Furthermore, as mirror 127, a half mirror or a beam splitter which transmits a portion of the emitted light beam and reflects another portion thereof may be used. Moreover, mirrors 127 may have a function of concentrating a light beam.

### Control Unit

Control unit 109 controls operation of distance measuring device 101 including light sources 103, mirror 105, and light receiving unit 107. Control unit 109 controls emission timing of pulsed light beam 115, for example, emitted from each light source 103, and senses the emission timing. Control unit 109 controls driving of mirror 105, and senses an inclination angle of mirror 105 and an angle of a normal to mirror 105. Control unit 109 detects a light receiving state of light receiving unit 107.

### Case

Case 111 is an outer packaging box which houses the optical system of distance measuring device 101. Inside case 111, the optical system including the plurality of light sources 103, mirror 105, light receiving unit 107, and the like is housed. Case 111 has a light shielding property. Desirably, the inside of case 111 is black in order to absorb stray light. Case 111 is provided with window 113 through which emitted light beam 121 and reflected light beam 125 pass.

### Window

Window 113 is an opening, and emitted light beam 121 is emitted through window 113 toward target 119. Reflected light beam 125 enters case 111 through window 113. Window 113 desirably shields a light beam from the outside of case 111. Window 113 is equipped with a window material having a wavelength characteristic corresponding to the wavelength of a light beam to be transmitted therethrough. As the window material, a window material having a wavelength characteristic that allows transmission of light beams 115 is mounted.

It should be noted that an optical system including different light paths for emitted light beam 121 and reflected light beam 125 may be adopted, and a plurality of windows including a window for emitted light beam 121 and a window for reflected light beam 125 may be provided as window 113. Window 113 may have a function of concentrating a light beam, or may have a function of diverging a light beam.

### Operation of Distance Measuring Device

Next, an example of operation of distance measuring device 101 will be described. As shown in FIG. 25, light distribution of light beam 115 emitted from each light source 103 is changed at lens 123. Light beam 115 penetrating lens 123 becomes a parallel light beam, for example. Light beam 115 as a parallel light beam penetrates mirror 127, or passes through the through hole (not shown) provided in mirror 127, and is reflected at mirror 105.

Light beams 115 reflected by mirror 105 are emitted from distance measuring device 101 toward target 119, as emitted light beam 121. Here, mirror 105 is reflector 3 of optical scanning device 1 (see FIG. 1), and light beams 115 are scanned in two dimensions as reflector 3 is torsionally driven. Light beams 115 scanned in two dimensions are emitted through window 113 toward target 119, as emitted light beam 121.

Emitted light beam 121 emitted to target 119 is reflected at target 119. Of the reflected light beam, a portion of reflected light beam 125 enters case 111 of distance measuring device 101 through window 113. Reflected light beam 125 entering case 111 is reflected at mirror 105, and is further reflected at mirrors 127, and then enters light receiving unit 107. Light receiving unit 107 senses entering reflected light beam 125. Control unit 109 measures a time from when light beams 115 are emitted from light sources 103 to when reflected light beam 125 is sensed by light receiving unit 107. Control unit 109 calculates a distance from vehicle 117 to target 119 based on the measured time.

Control unit 109 detects a direction of the normal to mirror 105 (reflector 3) which is torsionally driven. In this case, for example, a sensor for sensing a cycle at which mirror 105 is torsionally driven can be used. Further, control unit 109 can detect the direction of the normal from a drive signal of mirror 105. Control unit 109 calculates a direction in which emitted light beam 121 is emitted, based on positions of light sources 103 and the direction of the normal to mirror 105.

Control unit 109 calculates a direction and a distance in/at which target 119 is located with respect to vehicle 117, based on the direction in which emitted light beam 121 is emitted and the distance to target 119. Control unit 109 calculates the direction and the distance in/at which target 119 is located with respect to vehicle 117, based on emitted light beam 121 scanned at every moment and reflected light beam 125 sensed at every moment, and thereby obtains a distance image.

It should be noted that, although an optical system for emitted light beam 121 is the same as an optical system for reflected light beam 125 in distance measuring device 101 described above, the optical system for reflected light beam 125 may be different from the optical system for emitted light beam 121. Even with such optical systems, the distance to the target can be calculated based on emitted light beam 121 and sensed reflected light beam 125. Furthermore, a distance image around distance measuring device 101 (vehicle 117) including target 119 can be obtained based on emitted light beam 121 scanned at every moment and reflected light beam 125 sensed at every moment.

It should be noted that the optical scanning devices described in the respective embodiments can be variously combined as necessary.

It should be understood that the embodiments disclosed herein are illustrative and non-restrictive. The present disclosure is defined by the scope of the claims, rather than the scope described above, and is intended to include any modifications within the scope and meaning equivalent to the scope of the claims.

### Industrial Applicability

The present disclosure is effectively applicable to an optical scanning device to which MEMS technology is applied.

### Reference Signs List

1: optical scanning device; 3: reflector; 5: support body; 7: drive beam; 9: magnet; 10: drive unit; 11: first semiconductor layer; 13: first insulating layer; 15: second semiconductor layer; 16: side wall surface; 17: first insulating film; 19: second insulating film; 21: third insulating film; 24, 24a, 24b: electrode pad; 19a; via hole; 23: first wire; 25: second wire; 27: metal film; 27a: reflection surface; 29: rib; 31: protection film; 31a: first protection film; 31b: second protection film; 41: reflector region; 43: drive beam region; 45: support body region; 51: SOI substrate; 51a: opening; 53: C-SOI substrate; 12: third semiconductor layer; 12a: cavity; 61: fixed comb-like electrode; 63: movable comb-like electrode; 71: piezoelectric film; 101: distance measuring device; 103: light source; 105: mirror; 107: light receiving unit; 109: control unit; 111: case; 113: window; 115: light beam; 117: vehicle; 119: target; 121: emitted light beam; 123: lens; 125: reflected light beam; 127: mirror.

1. An optical scanning device comprising:
a reflector having a reflection surface;
a support body disposed to be spaced from the reflector;
a drive beam connecting the reflector and the support body; and
a drive unit to torsionally drive the reflector about the drive beam with respect to the support body,
the reflector, the support body, and the drive beam being provided on an SOI substrate,
in the drive beam, all surfaces of the drive beam including side surfaces of the drive beam being covered with at least one layer of a protection film including a first protection film.

2. The optical scanning device according to claim 1, wherein the first protection film includes at least one selected from the group consisting of a silicon oxide film, a silicon nitride film, an alumina film, and a titania film.

3. The optical scanning device according to claim 1, wherein the protection film includes a second protection film located more inward than the first protection film.

4. The optical scanning device according to claim 3, wherein the second protection film is a resin film.

5. The optical scanning device according to claim 4, wherein the resin film is one selected from the group consisting of an acrylic resin film, a polyimide-based resin film, and an epoxy-based resin film.

6. The optical scanning device according to claim 1, wherein
the drive beam includes a beam body,
the beam body has opposite side wall surfaces covered with the protection film, and
the side wall surfaces are planarized.

7. The optical scanning device according to claim 1, wherein
the drive unit includes
a wire disposed along an outer periphery of the reflector, and
a pair of magnets disposed to sandwich the reflector therebetween.

8. The optical scanning device according to claim 1, wherein the drive unit includes one of an electrostatic drive unit and a piezoelectric drive unit.

9. A method for manufacturing an optical scanning device having a reflector, a support body, and a drive beam, the method comprising:
preparing a substrate including a semiconductor layer formed on a support substrate with a first insulating film being interposed therebetween;
forming a reflection film having a reflection surface to serve as the reflector, on the semiconductor layer, with a second insulating film being interposed therebetween;
forming a drive unit to drive the reflector; and
forming the reflector having the reflection film, the support body disposed to be spaced from the reflector, and the drive beam connecting the reflector and the support body, by performing processing on the second insulating film, the semiconductor layer, the first insulating film, and the support substrate,
forming the drive beam including
patterning the semiconductor layer to serve as the drive beam, by performing etching treatment, and
forming at least one layer of a protection film including a first protection film, to cover all surfaces of the drive beam including side wall surfaces in a thickness direction of the patterned semiconductor layer.

10. The method for manufacturing the optical scanning device according to claim 9, wherein forming the drive beam includes removing a portion of the support substrate located immediately below the patterned semiconductor layer, after patterning the semiconductor layer and before forming the protection film.

11. The method for manufacturing the optical scanning device according to claim 9, wherein
preparing the substrate includes preparing the support substrate including a cavity formed in a portion of the support substrate located in a region where the drive beam is to be formed, and
forming the drive beam includes
forming the protection film in a state where the portion of the support substrate is located immediately below the drive beam with the cavity being sandwiched therebetween, after patterning the semiconductor layer, and
removing the portion of the support substrate located immediately below the drive beam, after forming the protection film.

12. The method for manufacturing the optical scanning device according to claim 9, wherein forming the protection film includes forming the first protection film by an atomic layer deposition method.

13. The method for manufacturing the optical scanning device according to claim 9, wherein forming the protection film includes forming the first protection film having a film thickness of 0.01 µm to 1.00 µm under a temperature condition of less than or equal to 300° C.

14. The method for manufacturing the optical scanning device according to claim 9, wherein forming the drive beam includes planarizing the side wall surfaces of the exposed semiconductor layer, after patterning the semiconductor layer.

15. A distance measuring device to which the optical scanning device according to claim 1 is applied, the distance measuring device comprising:
a light source to emit a light beam toward the optical scanning device;
the optical scanning device to reflect the light beam toward a target;
a light detector to detect the light beam reflected at the target; and
a control unit including control of operation of the optical scanning device.
